(19) United States
(12) Patent Application Publication
(10) Pub. No.: US 2013/0260318 A1
(43) Pub. Date: Oct. 3, 2013

(54) Repair Machine Based Glass Substrate Re-Marking Method and Glass Substrate Re-Marking Device

(71) Applicant: Shan Li, Shenzhen City (CN)

(72) Inventor: Shan Li, Shenzhen City (CN)

(73) Assignee: SHENZHEN CHINA STAR OPTOELECTRONICS TECHNOLOGY CO., LTD., Shenzhen City, Guangdong (CN)

(21) Appl. No.: 13/512,869

(22) PCT Filed: Mar. 27, 2012
(86) PCT No.: PCT/CN12/73962

§ 371 Date: May 30, 2012

(30) Foreign Application Priority Data
Mar. 27, 2012 (CN) 201210084571.9

(51) Int. Cl. B23K 26/38; G03F 7/20

(52) U.S. Cl. 430/322; 219/121.67

(57) ABSTRACT

Provided is a repair machine based glass substrate re-marking method, including (1) providing a repair machine and a digital micro-mirror device, in which the repair machine includes a main body, a carrier panel, a control unit, a storage unit, and a laser head; (2) mounting the digital micro-mirror device to the laser head and electrically connecting the digital micro-mirror device to the control unit; (3) placing a glass substrate to be marked on the carrier panel, the glass substrate having a photo-resist layer; (4) operating the control unit to retrieve a corresponding template pattern document from the storage unit and transmitting a template pattern signal of the template pattern document to the digital micro-mirror device; and (5) operating the laser head to emit a laser beam, which is projected by the digital micro-mirror device to the glass substrate to effect exposure of the photo-resist layer on the glass substrate.

### BACKGROUND OF THE INVENTION

1. Field of the Invention

The present invention relates to the field of manufacture process of glass substrate, and in particular to a repair machine based glass substrate re-marking method and a glass substrate re-marking device.

2. The Related Arts

In a manufacture process of glass substrate, lithography generally comprises four steps of photoresist coating, exposure, development, and inspection. Marking of the glass substrate (glass ID) is generally done in the process of lithography. The marking-completed glass substrates that are of the same batch and the same specification bear identical marking so that different batches or different specifications of glass substrate can be identified, avoiding unnecessary confusion.

In the process of lithography, glass substrate marking is carried out with a marker. When the marker gets out of order, it may happen that some of the glass substrates are not marked or are incompletely marked. These glass substrates that are not marked or are incompletely marked must be subjected to a re-marking process. The conventional re-marking process supplies the non-marked or incompletely-marked to a changer for classification. The non-marked glass substrates are then conveyed to other lithography line to be separately re-marked.

However, such a known process of re-marking takes time and may easily lead to mix of glass substrates of different batches.

### SUMMARY OF THE INVENTION

An objective of the present invention is to provide a repair machine based glass substrate re-marking method, which carries out on-line repair of glass substrates that are not marked in a lithographic process in order to reduce the time of re-marking process and also avoid undesired mix of glass substrates of different batches.

Another objective of the present invention is to provide a glass substrate re-marking device, which has a simple structure, is easy to operate, and helps simplifying a re-marking process.

To achieve the objectives, the present invention provides a repair machine based glass substrate re-marking method, which comprises the followings steps:

Step 1: providing a repair machine and a digital micro-mirror device, in which the repair machine comprise a main body, a carrier panel arranged on the main body, a control unit mounted to the main body, a storage unit electrically connected to the control unit, and a laser head mounted to the main body and located above the carrier panel, and the laser head is electrically connected to the control unit and the storage unit stores template pattern documents;

Step 2: mounting the digital micro-mirror device to the laser head and electrically connecting the digital micro-mirror device to the control unit;

Step 3: placing a glass substrate to be marked on the carrier panel, the glass substrate comprising a photo-resist layer formed thereon;

Step 4: operating the control unit to retrieve a corresponding template pattern document from the storage unit and transmitting a template pattern signal of the template pattern document to the digital micro-mirror device so that the digital micro-mirror device shows the template pattern according to the template pattern signal;

Step 5: operating the laser head to emit a laser beam, which is projected by the digital micro-mirror device to the glass substrate to effect exposure of the photo-resist layer on the glass substrate; and

Step 6: removing the glass substrate from the carrier panel to carry out development and etching processes.

The digital micro-mirror device comprises a rectangular array that is formed by composing a plurality of micro-mirrors and micro-electrodes respectively disposed under the micro-mirrors. The micro-electrodes are electrically connected to the control unit.

In Step 4, the control unit retrieves a corresponding template pattern document from the storage unit and carries out gray scale comparison on the template pattern document to identify borders of the template pattern in order to confirm the template pattern.

The present invention also provides a glass substrate re-marking device, which comprises a repair machine and a digital micro-mirror device. The repair machine comprises a main body, a carrier panel arranged on the main body, a control unit mounted to the main body, a storage unit electrically connected to the control unit, and a laser head mounted to the main body and located above the carrier panel. The laser head is electrically connected to the control unit. The storage unit stores template pattern documents. The digital micro-mirror device is mounted to the laser head and is electrically connected to the control unit.

The digital micro-mirror device comprises a rectangular array that is formed by composing a plurality of micro-mirrors and micro-electrodes respectively disposed under the micro-mirrors. The micro-electrodes are electrically connected to the control unit.

The efficacy of the present invention is that the present invention provides a repair machine based glass substrate re-marking method, which mounts a digital micro-mirror device to a laser head mounted on a repair machine to provide the repair machine with laser repair imaging function to thereby realize on-line repair of glass substrate marking, save the troubles of transferring the glass substrate to other lithography line for separate re-marking and also avoid the potential risk of mixing during the batching of the glass substrates. The present invention also provides a glass substrate re-marking device that has a simple structure, is easy to operate, and helps simplifying a re-marking process.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, will be apparent from the following detailed description of an embodiment of the present invention, with reference to the attached drawings. In the drawings:

FIG. 1 is a flow chart showing a repair machine based glass substrate re-marking method according to the present invention; and

FIG. 2 is a schematic view showing a glass substrate re-marking device according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

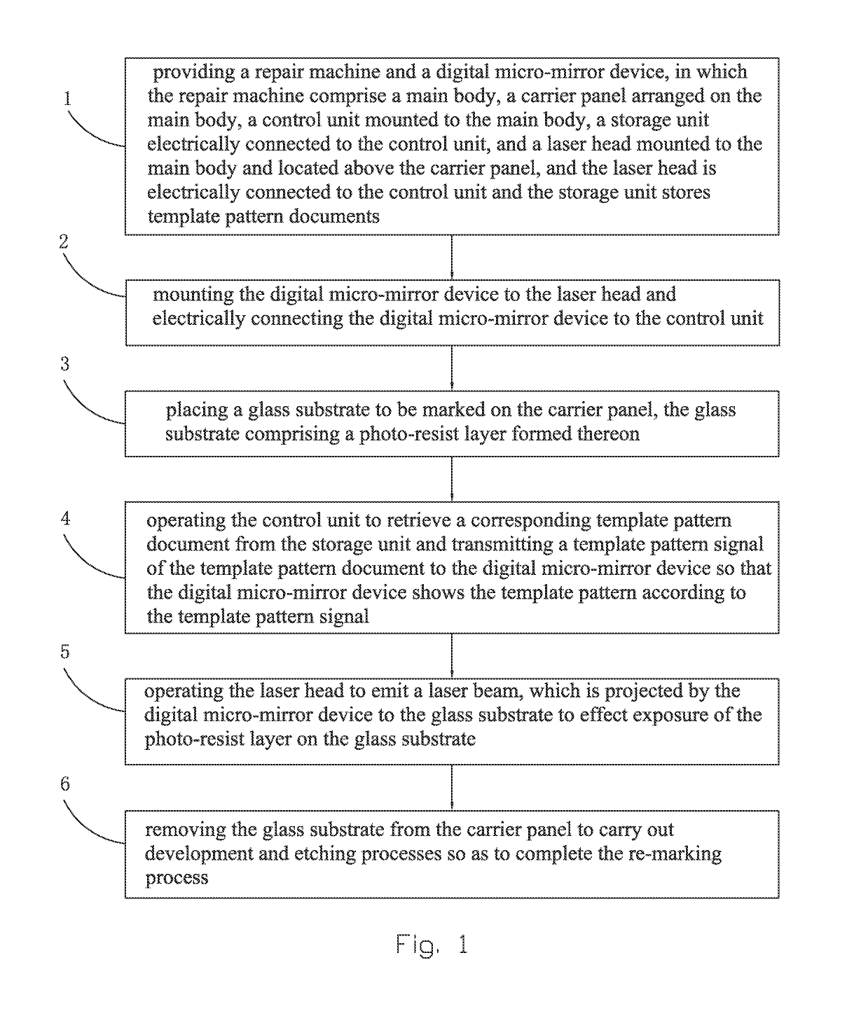

Referring to FIG. 1, the present invention provides a repair machine based glass substrate re-marking method, which comprises the following steps:

Step 1: providing a repair machine and a digital micro-mirror device (DMD), in which the repair machine comprise a main body, a carrier panel arranged on the main body, a control unit mounted to the main body, a storage unit electrically connected to the control unit, and a laser head mounted to the main body and located above the carrier panel, and the laser head is electrically connected to the control unit and the storage unit stores template pattern documents;

Step 2: mounting the digital micro-mirror device to the laser head and electrically connecting the digital micro-mirror device to the control unit;

Step 3: placing a glass substrate to be marked on the carrier panel, the glass substrate comprising a photo-resist layer formed thereon;

Step 4: operating the control unit to retrieve a corresponding template pattern document from the storage unit and transmitting a template pattern signal of the template pattern document to the digital micro-mirror device so that the digital micro-mirror device shows the template pattern according to the template pattern signal;

Step 5: operating the laser head to emit a laser beam, which is projected by the digital micro-mirror device to the glass substrate to effect exposure of the photo-resist layer on the glass substrate; and

Step 6: removing the glass substrate from the carrier panel to carry out development and etching processes so as to complete the re-marking process.

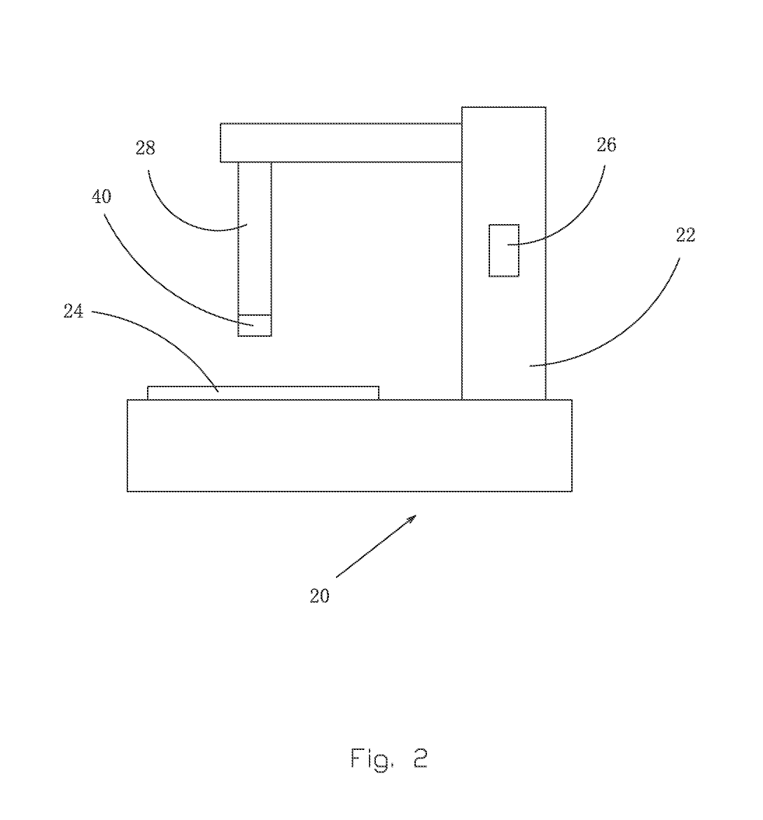

Also referring to FIG. 2, as an embodiment of the present invention, the repair machine 20 is an Olympus repair machine, which comprises a main body 22, a carrier panel 24 arranged on the main body 22, a control unit 26 mounted to the main body 22, a storage unit (not shown) electrically connected to the control unit 26, and a laser head 28 mounted to the main body 22 and located above the carrier panel 24. The laser head 28 is electrically connected to the control unit 26. The storage unit stores template pattern documents. A digital micro-mirror device 40 is mounted to the laser head 28 and is electrically connected to the control unit 26. The digital micro-mirror device 40 comprises a rectangular array that is formed by composing a plurality of micro-mirrors (not shown) and micro-electrodes (not sown) respectively disposed under the micro-mirrors. The micro-electrodes are electrically connected to the control unit 26. The repair machine 20 and the digital micro-mirror device 40 are both realized with the known techniques.

During the manufacture process, the control unit 26 retrieves a corresponding template pattern document from the storage unit to acquire individual laser marking instructions and carries out gray scale comparison on the template pattern document to identify borders of the template pattern. Afterwards, a determination is made on whether the template borders match actual pattern borders. If they do not match, gray scale comparison is conducted again until the template borders match the actual pattern borders. Then, a signal of the template pattern is transmitted to the digital micro-mirror device 40 so that the digital micro-mirror device 40 adjusts the micro-mirrors and the micro-electrodes according to the template pattern signal for gray scale conversion in order to completely show the template pattern, whereby the digital micro-mirror device 40 may serve as a mask carrying the template pattern. Afterwards, laser marking is performed, wherein the laser head 28 emits a laser beam, which is projected by the digital micro-mirror device 40 to effect exposure of the photo-resist layer coated on the glass substrate to be marked and thus an un-exposed photo-resist layer that is identical to the template pattern is formed at the site where re-marking is to be made. Finally, development and etching processes are carried out to display the template pattern and thus completing the re-marking process and realizing on-line repair of glass substrate marking. This saves the troubles of transferring the glass substrate to other lithography line for separate re-marking and also avoids the potential risk of mixing during the batching of the glass substrates.

Referring to FIG. 2, the present invention also provides a glass substrate re-marking device, which comprises a repair machine 20 and a digital micro-mirror device 40. The repair machine 20 comprises a main body 22, a carrier panel 24 arranged on the main body 22, a control unit 26 mounted to the main body 22, a storage unit (not shown) electrically connected to the control unit 26, and a laser head 28 mounted to the main body 22 and located above the carrier panel 24. The laser head 28 is electrically connected to the control unit 26. The storage unit stores template pattern documents. The digital micro-mirror device 40 is mounted to the laser head 28 and is electrically connected to the control unit.

The digital micro-mirror device 40 comprises a rectangular array that is formed by composing a plurality of micro-mirrors (not shown) and micro-electrodes (not sown) respectively disposed under the micro-mirrors. The micro-electrodes are electrically connected to the control unit.

The present invention provides a glass substrate re-marking device that has a simple structure, is easy to operate, and helps simplifying a re-marking process and realizes on-line repair of glass substrate marking so as to save the troubles of transferring the glass substrate to other lithography line for separate re-marking and also avoid the potential risk of mixing during the batching of the glass substrates.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A repair machine based glass substrate re-marking method, comprising the followings steps:
Step 1: providing a repair machine and a digital micro-mirror device, in which the repair machine comprise a main body, a carrier panel arranged on the main body, a control unit mounted to the main body, a storage unit electrically connected to the control unit, and a laser head mounted to the main body and located above the carrier panel, and the laser head is electrically connected to the control unit and the storage unit stores template pattern documents;
Step 2: mounting the digital micro-mirror device to the laser head and electrically connecting the digital micro-mirror device to the control unit;
Step 3: placing a glass substrate to be marked on the carrier panel, the glass substrate comprising a photo-resist layer formed thereon;
Step 4: operating the control unit to retrieve a corresponding template pattern document from the storage unit and transmitting a template pattern signal of the template pattern document to the digital micro-mirror device so that the digital micro-mirror device shows the template pattern according to the template pattern signal; and
Step 5: operating the laser head to emit a laser beam, which is projected by the digital micro-mirror device to the glass substrate to effect exposure of the photo-resist layer on the glass substrate.

2. The repair machine based glass substrate re-marking method as claimed in claim 1 further comprising Step 6 of removing the glass substrate from the carrier panel to carry out development and etching processes.

3. The repair machine based glass substrate re-marking method as claimed in claim 1, wherein the digital micro-mirror device comprises a rectangular array that is formed by composing a plurality of micro-mirrors and micro-electrodes respectively disposed under the micro-mirrors, the micro-electrodes being electrically connected to the control unit.

4. The repair machine based glass substrate re-marking method as claimed in claim 1, wherein in Step 4, the control unit retrieves a corresponding template pattern document from the storage unit and carries out gray scale comparison on the template pattern document to identify borders of the template pattern in order to confirm the template pattern.

5. A repair machine based glass substrate re-marking method, comprising the followings steps:
Step 1: providing a repair machine and a digital micro-mirror device, in which the repair machine comprises a main body, a carrier panel arranged on the main body, a control unit mounted to the main body, a storage unit electrically connected to the control unit, and a laser head mounted to the main body and located above the carrier panel, and the laser head is electrically connected to the control unit and the storage unit stores template pattern documents;
Step 2: mounting the digital micro-mirror device to the laser head and electrically connecting the digital micro-mirror device to the control unit;
Step 3: placing a glass substrate to be marked on the carrier panel, the glass substrate comprising a photo-resist layer formed thereon;
Step 4: operating the control unit to retrieve a corresponding template pattern document from the storage unit and transmitting a template pattern signal of the template pattern document to the digital micro-mirror device so that the digital micro-mirror device shows the template pattern according to the template pattern signal;
Step 5: operating the laser head to emit a laser beam, which is projected by the digital micro-mirror device to the glass substrate to effect exposure of the photo-resist layer on the glass substrate;
Step 6: removing the glass substrate from the carrier panel to carry out development and etching processes;
wherein the digital micro-mirror device comprises a rectangular array that is formed by composing a plurality of micro-mirrors and micro-electrodes respectively disposed under the micro-mirrors, the micro-electrodes being electrically connected to the control unit; and
wherein in Step 4, the control unit retrieves a corresponding template pattern document from the storage unit and carries out gray scale comparison on the template pattern document to identify borders of the template pattern in order to confirm the template pattern.

6. A glass substrate re-marking device, comprising a repair machine and a digital micro-mirror device, the repair machine comprising a main body, a carrier panel arranged on the main body, a control unit mounted to the main body, a storage unit electrically connected to the control unit, and a laser head mounted to the main body and located above the carrier panel, the laser head being electrically connected to the control unit, the storage unit storing template pattern documents, the digital micro-mirror device being mounted to the laser head and electrically connected to the control unit.

7. The glass substrate re-marking device as claimed in claim 6, wherein the digital micro-mirror device comprises a rectangular array that is formed by composing a plurality of micro-mirrors and micro-electrodes respectively disposed under the micro-mirrors, the micro-electrodes being electrically connected to the control unit.
